(19) United States
(12) Patent Application Publication
(10) Pub. No.: US 2013/0020640 A1
(43) Pub. Date: Jan. 24, 2013

(54) SEMICONDUCTOR DEVICE STRUCTURE INSULATED FROM A BULK SILICON SUBSTRATE AND METHOD OF FORMING THE SAME

(71) Applicants: John Y. CHEN, Cupertino, CA (US); Boon-Khim Liew, Saratoga, CA (US)

(72) Inventors: John Y. CHEN, Cupertino, CA (US); Boon-Khim Liew, Saratoga, CA (US)

(21) Appl. No.: 13/185,373

(22) Filed: Jul. 18, 2011

(51) Int. Cl. H01L 29/772; H01L 21/31

(52) U.S. Cl. 257/347; 438/759; 257/E21.24; 257/E29.242

(57) ABSTRACT

A structure making up a part of a semiconductor device, such as a fin structure of a finFET device, is formed on and electrically isolated from a semiconductor substrate. The structure is comprised of the semiconductor substrate material and is electrically isolated from a remaining portion of the semiconductor substrate by an insulating barrier. The insulating barrier is formed by an isotropic oxidation process that oxidizes portions of the semiconductor substrate that are not protected by an oxidation barrier.

### BACKGROUND OF THE INVENTION

1. Field of the Invention

Embodiments of the present invention relate generally to semiconductor manufacturing and, more specifically, to a semiconductor device structure insulated from a bulk silicon substrate and a method of forming the same.

2. Description of the Related Art

Increasing device densities in integrated circuits has led to continuing improvements in device performance and cost. To facilitate further increases in device density, new technologies are constantly needed to allow the feature size of semiconductor devices to be reduced.

One type of semiconductor device used to facilitate increased device density is a fin field effect transistor, or finFET. Unlike more traditional planar transistors, finFETs are three-dimensional structures in which the body of the transistor is formed from a vertical structure, generally referred to as a “fin,” and the gate of the transistor is formed on two or more sides of the fin. FinFETs generally allow better gate control of the current of the short channel FET device, and consequently facilitate increased device densities in an integrated circuit without reducing device performance or increasing power dissipation.

An important drawback in the design and fabrication of finFETs is that each finFET device generally needs to be electrically isolated in two ways. First, each finFET needs to be isolated from adjacent finFETs, and second, the source and drain in a particular finFET device need to be isolated from each other to ensure source-to-drain decoupling, since source-to-drain decoupling prevents or minimizes off-state leakage between the source and drain. For this reason, to provide such electrical isolation finFETs have been manufactured on (1) silicon-on-insulator (SOI) wafers, or (2) bulk silicon substrates using additional processing steps to form a dielectric layer between the fins and a highly doped silicon layer below the fins. In the first case, the fin structure of a finFET on an SOI wafer is formed from the silicon layer above the buried isolation layer, which is usually a silicon dioxide layer. Each fin is thus isolated from adjacent fins by virtue of the buried isolation layer beneath the fins. Likewise, the source and drains of a particular finFET on an SOI wafer are also decoupled from each other by the buried isolation layer. In the second case, finFETS on a bulk silicon substrate are formed with a thick isolation layer, e.g., silicon dioxide, between the fins. Each fin is thus isolated from adjacent fins by virtue of the isolation layer between the fins. In addition, a highly doped silicon layer is formed below each fin, usually by ion implantation, to reduce the leakage between source and drain that takes place via the bulk semiconductor material of the semiconductor substrate disposed underneath the fin.

Each of the above-described approaches has significant drawbacks. While the use of SOI wafers provides needed isolation for finFETs, the added cost for SOI wafers compared to bulk silicon wafers can be prohibitive. For example, SOI wafers can commonly cost two to three times as much as bulk silicon wafers. In addition, the use of SOI wafers is not compatible with all semiconductor fabrication processes. When forming finFETs on a bulk semiconductor substrate, the additional process steps to form finFET on bulk silicon substrate present process challenges in etching taller fins and forming a thick isolation layer between fins, which result in lower device density. Furthermore, the highly doped silicon layer below the fin results in degraded electrical properties, i.e., lower current density and/or higher turn-on voltage.

As the foregoing illustrates, there is a need in the art for a semiconductor device structure insulated from a bulk silicon substrate and method of forming the same.

### SUMMARY OF THE INVENTION

One embodiment of the present invention sets forth a semiconductor device structure formed on and electrically isolated from a semiconductor substrate and methods for forming the same. The structure is part of a semiconductor device comprised of the semiconductor substrate material, and is electrically isolated from a remaining portion of the semiconductor substrate by an insulating barrier. The insulating barrier is formed by an isotropic oxidation process that oxidizes portions of the semiconductor substrate that are not protected by an oxidation barrier.

One advantage of the present invention is that semiconductor devices that benefit from having an underlying electrical isolation layer, e.g., a low-leakage finFET device, can be produced from a bulk silicon wafer, rather than from a silicon-on-insulator wafer. In addition, embodiments of the present invention allow devices formed with semiconductor fabrication processes that are not compatible with silicon-on-insulator wafers to advantageously use an underlying electrical isolation layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic perspective view of a fin field effect transistor (finFET), according to an embodiment of the invention;

FIG. 2 is a cross-sectional view of the finFET device illustrated in FIG. 1 taken at section 2-2 in FIG. 1;

FIG. 3 is a cross-sectional view of the finFET illustrated in FIG. 1 taken at section 3-3 in FIG. 2;

FIGS. 4A-E illustrate schematic side views of electrically insulating barrier 200 being formed in accordance with one embodiment of the invention;

FIGS. 5A-C illustrate views of a bulk semiconductor substrate from the cross-sectional view taken at section 3-3 in FIG. 2, according to one embodiment of the invention;

FIG. 6 is a schematic perspective view of a finFET device having multiple fin structures, according to an embodiment of the invention; and

FIG. 7 sets forth a flowchart of method steps for forming a device on a semiconductor substrate, according to an embodiment of the invention.

For clarity, identical reference numbers have been used, where applicable, to designate identical elements that are common between figures. It is contemplated that features of one embodiment may be incorporated in other embodiments without further recitation.

### DETAILED DESCRIPTION

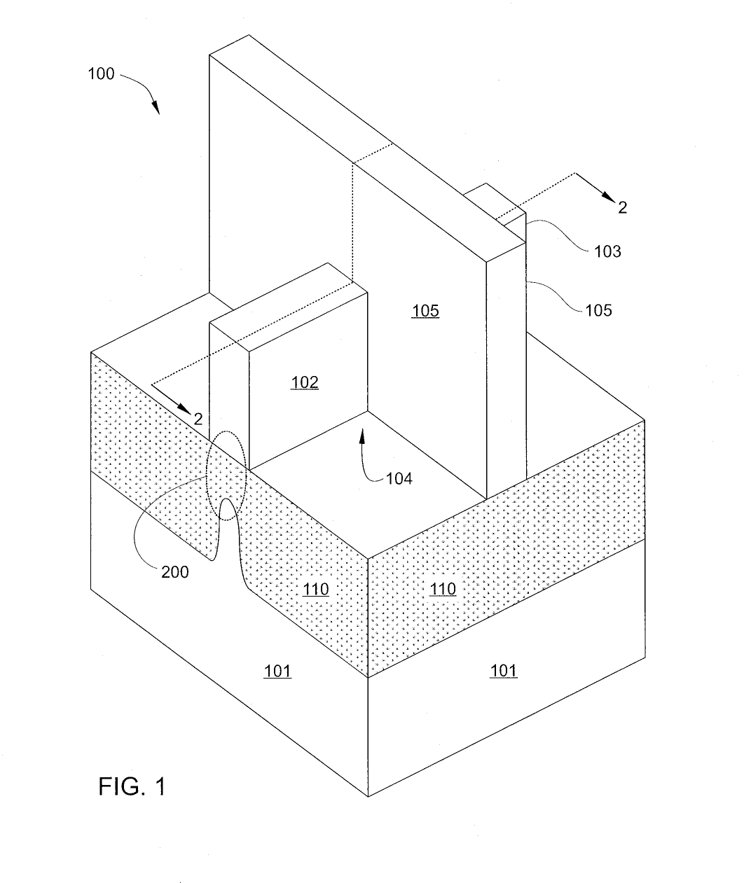

FIG. 1 is a schematic perspective view of a fin field effect transistor (finFET) device 100, according to an embodiment of the invention. FinFET device 100 may be configured as an nMOSFET or a pMOSFET, is formed on a bulk semiconductor substrate 101, and includes a source region 102, a drain region 103, a channel region 104, and a gate conductor 105. FinFET device 100 is electrically isolated from other finFET devices formed on bulk semiconductor substrate 101 by field oxide (FOX) layer 110 and by an electrically insulating barrier 200. In addition, source region 102 and drain region 103 are electrically isolated from each other by electrically insulating barrier 200.

Bulk semiconductor substrate 101 is a bulk semiconductor substrate that is fabricated using techniques well known in the art and may have any suitable crystallographic orientation including, for example, (110), (100) or (111). In some embodiments, bulk semiconductor substrate 101 comprises a bulk silicon wafer or a portion of a bulk silicon wafer. In other embodiments, bulk semiconductor substrate 101 comprises one or more other semiconductor materials, such as gallium arsenide (GaAs), silicon-germanium (SiGe) and/or germanium (Ge). In some embodiments, bulk semiconductor substrate 101 may also be doped as required to facilitate the formation of traditional planar MOSFET and/or other semiconductor devices thereon.

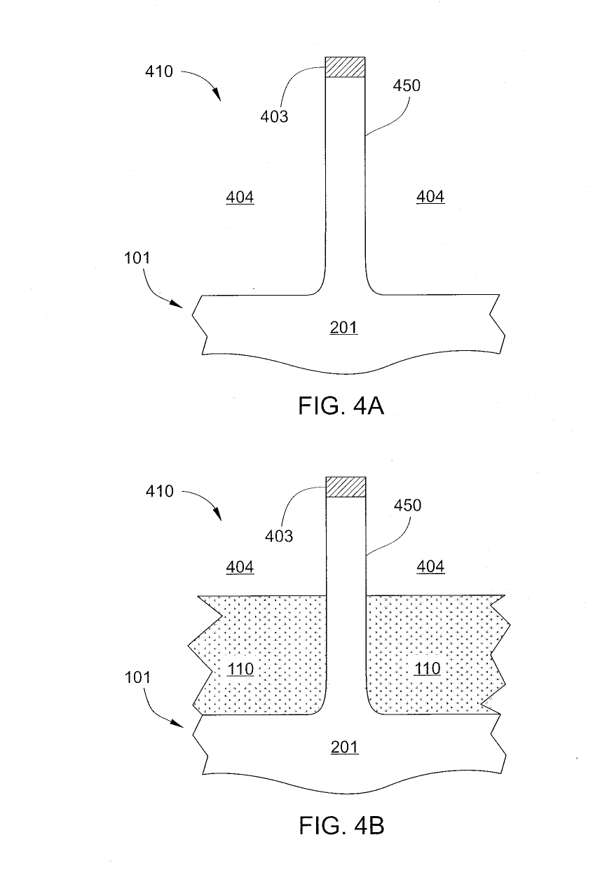

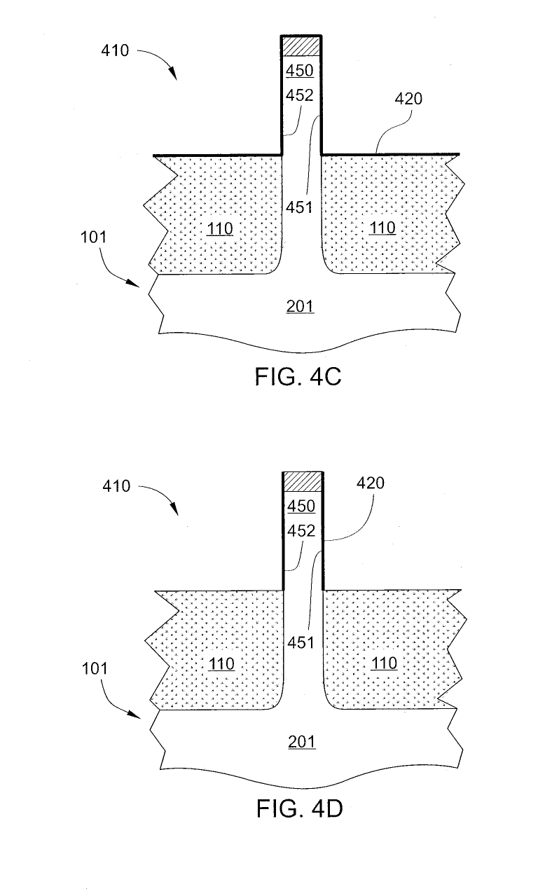

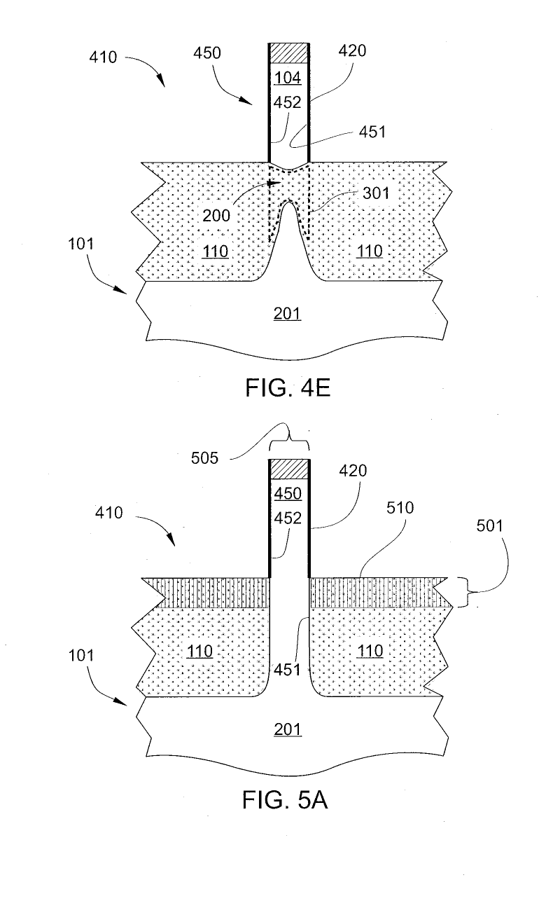

Channel region 104 serves as the conducting channel for finFET device 100. In some embodiments, channel region 104 is formed from the bulk semiconductor material of bulk semiconductor substrate 101, for example by removing surrounding material with one or more etch processes known in the art. Alternatively, channel region 104 may be epitaxially grown from the surface of bulk semiconductor substrate 101. In either case, when channel region 104 is initially formed on a surface of bulk semiconductor substrate 101, no dielectric layer is present between channel region 104 and bulk semiconductor substrate 101. In this invention, electrically insulating barrier 200 is created between channel region 104 and the bulk portion of bulk semiconductor substrate 101 after the formation of channel region 104. The formation of electrically insulating barrier 200 and channel region 104 is described below in conjunction with FIGS. 4A-E. In some embodiments, channel region 104 is doped to function as either an n-type or p-type material, depending on the configuration of finFET device 100.

Source region 102 and drain region 103 serve as the source and drain regions, respectively, for finFET device 100. Consequently, in some embodiments, source region 102 and drain region 103 comprise heavily doped semiconductor regions that are doped as required to enable finFET device 100 to act as a field effect transistor. Source region 102 is coupled to a source contact and drain region 103 is coupled to a drain contact. Source and drain contacts for finFET 100 are not shown in FIG. 1 for clarity.

Gate conductor 105 is used to induce a conducting channel between source region 102 and drain region 103 as desired. Gate conductor 105 generally comprises any suitable conductive material including doped polysilicon, doped SiGe, a conductive elemental metal, an alloy of a conductive elemental metal, a nitride or silicide of a conductive elemental metal or multilayers thereof, and the like. Gate conductor 105 is deposited, patterned and etched after the formation of channel region 104.

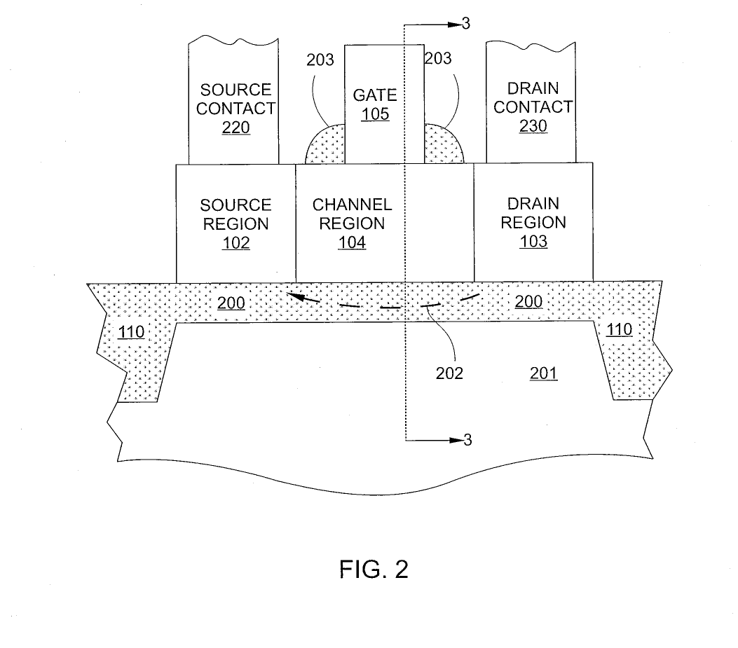

Field oxide layer 110 helps to electrically isolate finFET device 100 from adjacent finFET devices and comprises a dielectric material, such as silicon dioxide (SiO₂). Electrically insulating barrier 200, which further electrically isolates finFET device 100, is described below in conjunction with FIG. 2.

FIG. 2 is a cross-sectional view of the finFET device illustrated in FIG. 1, taken at section 2-2 (denoted by dotted line) in FIG. 1. As shown, electrically insulating barrier 200 is formed between finFET device 100 and underlying bulk semiconductor material 201 of bulk semiconductor substrate 101. Electrically insulating barrier 200 includes a dielectric material formed from the underlying bulk semiconductor material 201 of bulk semiconductor substrate 101. For example, in an embodiment in which bulk semiconductor substrate 101 is a bulk silicon wafer, electrically insulating barrier 200 is made up of silicon dioxide formed by performing an oxidation process on a portion of underlying bulk semiconductor material 201 and a bottom portion of channel region 104. Because electrically insulating barrier 200 is a dielectric material, source region 102 and drain region 103 are electrically isolated from each other, and no significant leakage path exists therebetween. With no leakage path between source region 102 and drain region 103, idle power required by finFET device 100 is significantly reduced. In contrast, a finFET device formed on bulk semiconductor substrate 101 and having no electrical isolation between the finFET device and underlying bulk semiconductor material 201 will suffer significant off-state leakage between source region 102 and drain region 103. For reference, such a leakage path 202 is depicted in FIG. 2.

Also shown in FIG. 2 are spacers 203, gate conductor 105, field oxide layer 110, a source contact 220 and a drain contact 230. Spacers 203 include a dielectric material and electrically isolate gate conductor 105 from source region 102 and drain region 103. Source contact 220 and drain contact 230 penetrate an insulating layer (not shown) between finFET device 100 and a metal interconnect to make an electrical connection between finFET device 100 and the metal interconnect.

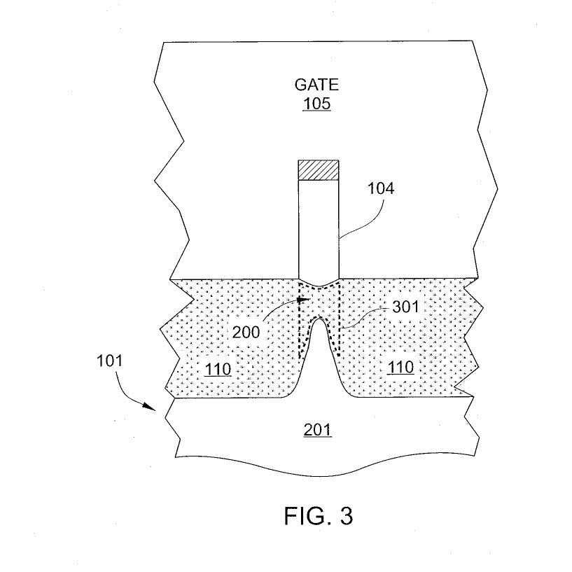

FIG. 3 is a cross-sectional view of the finFET illustrated in FIG. 1 taken at section 3-3 in FIG. 2. As shown, electrically insulating barrier 200 is disposed between channel region 104 and underlying bulk semiconductor material 201 of bulk semiconductor substrate 101. According to embodiments of the invention, electrically insulating barrier 200 is formed from a portion 301 of underlying bulk semiconductor material 201 that is adjacent to channel region 104. An oxidation process is used to convert bulk semiconductor material in portion 301 of underlying bulk semiconductor material 201 to a dielectric material. For example, in an embodiment in which bulk semiconductor substrate 101 is a bulk silicon wafer, electrically insulating barrier 200 is made up of silicon dioxide formed by such an oxidation process. A process by which electrically insulating barrier 200 is formed between channel region 104 and underlying bulk semiconductor material 201 is described below in conjunction with FIGS. 4A-E.

FIGS. 4A-E are schematic side views of electrically insulating barrier 200 being formed in accordance with one embodiment of the invention. FIGS. 4A-E view bulk semiconductor substrate 101 from the cross-sectional view taken at section 3-3 in FIG. 2.

FIG. 4A illustrates a surface region 410 of bulk semiconductor substrate 101 after a bulk semiconductor structure 450 has been formed thereon. In some embodiments, bulk semiconductor structure 450 is formed from underlying bulk semiconductor material 201 of bulk semiconductor substrate 101. Conventional patterning and etching techniques commonly known in the art may be used to form bulk semiconductor structure 450. For example, a hard mask layer may be deposited and patterned on bulk semiconductor substrate 101, and suitably located trenches 404 may be etched from bulk semiconductor substrate 101 using a directional etching process such as reactive ion etch (RIE). By etching two trenches 404 proximate each other, bulk semiconductor structure 450 can be formed as shown. In FIG. 4A, a remainder portion 403 of a hard mask material is shown disposed on top of bulk semiconductor structure 450 after the etching process.

FIG. 4B illustrates surface region 410 after the deposition of field oxide layer 110 into trenches 404. In some embodiments, field oxide layer 110 may be formed as shown using a chemical vapor deposition (CVD) process known in the art. Field oxide layer 110 acts as the shallow trench isolation (STI) between devices formed on surface region 410.

FIG. 4C illustrates surface region 410 after the deposition of a conformal oxidation barrier 420, using deposition processes known in the art. Conformal oxidation barrier 420 comprises a material selected to prevents oxygen from penetrating bulk semiconductor structure 450 during a subsequent oxidation process used to form electrically insulating barrier 200. A conformal process is used to deposit conformal oxidation barrier 420 so that sidewalls 451, 452 of bulk semiconductor structure 450 are covered by conformal oxidation barrier 420. In some embodiments, conformal oxidation barrier 420 comprises silicon nitride (Si₃N₄) deposited with a CVD process, such as a plasma-enhanced CVD process (PECVD).

FIG. 4D illustrates surface region 410 after the selective removal of conformal oxidation barrier 420, using one or more anisotropic etching process known in the art, such as RIE. As shown, an anisotropic etching process removes conformal oxidation barrier 420 formed on surface 411 of field oxide layer 110, while the conformal oxidation barrier 420 deposited on sidewalls 451, 452 of bulk semiconductor structure 450 remains in place. Removal of conformal oxidation barrier 420 from surface 411 allows a subsequent oxidation process to form electrically insulating barrier 200, as shown in FIG. 4E.

FIG. 4E illustrates surface region 410 after an isotropic oxidation process is used to oxidize portion 301 of underlying bulk semiconductor material 201. In some embodiments, the isotropic oxidation process used to oxidize portion 301 may be a thermal oxidation process. Ordinarily, the isotropic nature of oxidation processes, such as thermal oxidation, is considered a drawback, since the oxide so formed grows in all directions and therefore can encroach undesirably on active regions in a semiconductor device. However, embodiments of the invention utilize the non-directional nature of oxide growth from field oxide layer 110 into portions of bulk semiconductor material 201 to form electrically insulating barrier 200 between channel region 104 and underlying bulk semiconductor material 201. Thus, electrically insulating barrier 200 is an immersed dielectric region formed after channel region 104 has already been formed from bulk semiconductor structure 450. As shown, channel region 104 is electrically isolated from underlying bulk semiconductor material 201 as a result of the isotropic oxidation process, thereby effectively eliminating leakage path 202 between source region 102 and drain region 103 as depicted in FIG. 2. Conformal oxidation barrier 420 can subsequently be removed from sidewalls 451, 452 after the oxidation process, and conventional finFET manufacturing processes known in the art can then be used to complete the formation of finFET device 100 on surface region 410.

Thus, according to embodiments of the invention, a finFET device can be fabricated on a bulk semiconductor substrate that has the low off-state leakage current normally only achievable by finFET devices formed using silicon-on-insulator (SOI) substrates. Consequently, bulk semiconductor substrates may be used to form low-leakage finFET devices rather than the more expensive SOI substrates. In addition, devices requiring semiconductor fabrication processes that are incompatible with the use of SOI substrates can benefit from embodiments of the invention, since a low-leakage architecture for such devices is now available through the formation of an electrically insulating barrier between the devices and underlying bulk semiconductor material. Further, embodiments of the invention facilitate the formation of traditional planar MOSFET and/or other semiconductor devices on a common substrate with finFET devices that ordinarily must be formed on an SOI substrate.

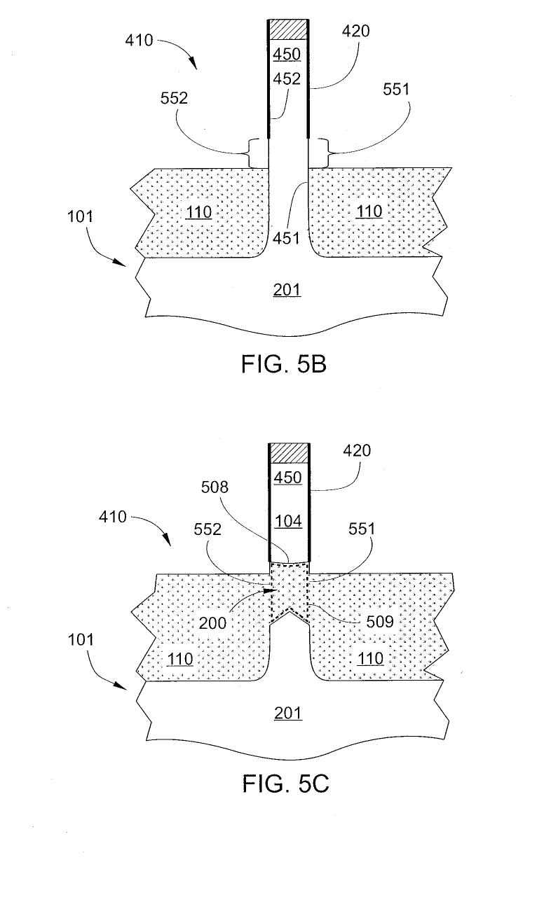

According to some embodiments, the topology of channel region 104 is improved by exposing the sidewalls of bulk semiconductor structure 450 prior to the isotropic oxidation process that forms electrically insulating barrier 200. FIGS. 5A-C illustrate one such embodiment. FIGS. 5A-C are schematic side views of electrically insulating barrier 200 being formed in accordance with an embodiment of the invention. FIGS. 5A-C illustrate views of bulk semiconductor substrate 101 from the cross-sectional view taken at section 3-3 in FIG. 2, according to one embodiment of the invention.

FIG. 5A illustrates surface region 410 after the selective removal of conformal oxidation barrier 420 from the surface of field oxide layer 110 and prior to the isotropic oxidation process that is used to oxidize a portion of underlying bulk semiconductor material 201. In addition, field oxide layer 110 has been damaged to a desired depth 501 to produce a damaged oxide layer 510. Depth 501 depends on the thickness 505 of bulk semiconductor structure 450, the particular semiconductor material making up bulk semiconductor structure 450, and the process temperature of the subsequent isotropic oxidation process to be performed on surface region 410. Accordingly, depth 501 can readily be determined by one of ordinary skill in the art for a particular configuration of finFET device 100. In one embodiment, field oxide layer 110 is damaged using an ion implantation process, which allows precise control of depth 501.

FIG. 5B illustrates surface region 410 after damaged oxide layer 510 has been removed. In some embodiments, damaged oxide layer 510 is removed using a wet etch process, such as an HF-based process, while in other embodiments, other material removal processes may be used. The removal of material from the surface of field oxide layer 110 exposes surface 551 on sidewall 451 and surface 552 on sidewall 452 of bulk semiconductor structure 450. Damaged oxide layer 510 is subject to much higher etch rates than the undamaged portion of field oxide layer 110, so the formation of damaged oxide layer 510 facilitates removal of only damaged oxide layer 510 by a subsequent chemical etching process. Alternatively, in some embodiments, damaged oxide layer 510 is not formed in field oxide layer 110 as described above. Instead, undamaged oxide material is removed from the exposed surface of field oxide layer 110 to expose surfaces 551, 552 as shown in FIG. 5B. In such embodiments, an anisotropic etching process may be used to remove undamaged oxide material from field oxide layer 110, such as RIE. In some embodiments, the same etching process used to selectively remove the portion of conformal oxidation barrier 420 formed on surface 411 of field oxide layer 110 is the same process used to remove undamaged oxide material from field oxide layer 110.

FIG. 5C illustrates surface region 410 after an isotropic oxidation process is used to oxidize portion 509 of underlying bulk semiconductor material 201 adjacent to the portion of bulk semiconductor structure 450 used to form channel region 104. The oxidation of portion 509 forms electrically insulating barrier 200. As shown in FIG. 5C, when surfaces 551, 552 are exposed prior to the oxidation process, oxide grows laterally, i.e., in the direction orthogonal to surfaces 551, 552, substantially faster than vertically, i.e., in the direction parallel to surfaces 551, 552. Consequently, the isotropic oxidation process forms a substantially planar interface 508 with electrically insulating barrier 200, which is a more uniform and desirable surface geometry for the bottom surface of channel region 104 than when the oxidation process is initiated with no exposed sidewall surfaces such as surfaces 551, 552. It is noted that as a result of the isotropic oxidation process used to oxidize portion 509 of underlying bulk semiconductor material 201, field oxide layer 110 becomes thicker, partially covering previously exposed surfaces 551, 552 on bulk semiconductor structure 450.

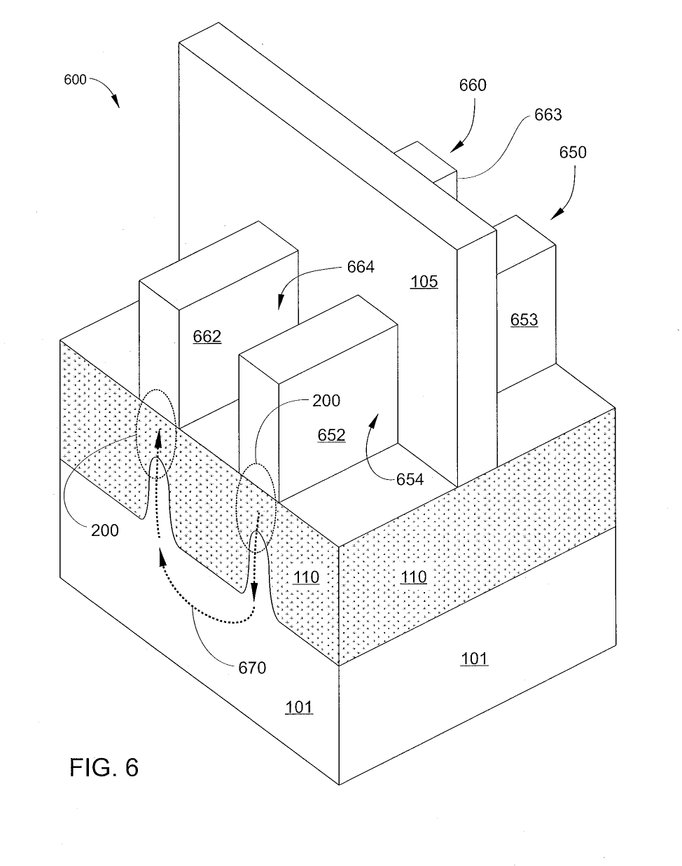

FIG. 6 is a schematic perspective view of a finFET device 600 having multiple fin structures, according to an embodiment of the invention. FinFET 600 is substantially similar in organization and operation to finFET device 100, except that finFET device 600 includes fin structures 650 and 660. Fin structure 650 includes a source region 652, a drain region 653, and a channel region 654. Similarly, fin structure 660 includes a source region 662, a drain region 663, and a channel region 664. As shown, fin structure 650 is electrically isolated from fin structure 660 by electrically insulating barriers 200. Specifically, significant leakage between fin structures 650 and 660 can occur along leakage path 670 if electrically insulating barriers 200 are not present as shown. Thus, according to embodiments of the invention, fin structures 650, 660 are electrically isolated from each other without using an SOI wafer for fabricating finFET device 600 or by highly doping a portion of the bulk semiconductor material disposed under each fin structure.

While embodiments of the invention are described herein with respect to a finFET device, one of skill in the art will appreciate that the formation of an electrically insulating barrier between a bulk semiconductor device and underlying bulk semiconductor material may be beneficial for other semiconductor devices as well. Similarly, while finFET device 100 has been described herein as a specific configuration of a non-planar transistor device, one of skill in the art will appreciate that embodiments of the invention are equally applicable to any non-planar finFET devices known in the art.

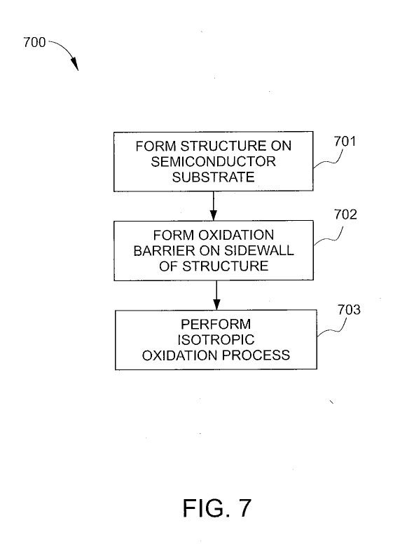

FIG. 7 sets forth a flowchart of method steps for forming a device on a semiconductor substrate, according to an embodiment of the invention. Although the method steps are described with respect to finFET device 100 of FIG. 1, persons skilled in the art will understand that performing the method steps, in any order, to form any other semiconductor device is within the scope of the invention.

As shown, the method 700 begins at step 701, where bulk semiconductor structure 450 is formed from the semiconductor substrate. Bulk semiconductor structure 450 has sidewalls 451, 452, and is comprised of the material of the semiconductor substrate, e.g., monocrystalline silicon.

In step 702, conformal oxidation barrier 420 is formed on sidewalls, 451, 452 of bulk semiconductor structure 450.

In step 703, an isotropic oxidation process, such as a thermal oxidation process, is performed to create electrically insulating barrier 200, which electrically isolates bulk semiconductor structure 450 from underlying bulk semiconductor material 201 of semiconductor substrate 101.

In sum, embodiments of the invention set forth a semiconductor device structure formed on and electrically isolated from a semiconductor substrate and methods for forming the same. One advantage of the present invention is that semiconductor devices that benefit from having an underlying electrical isolation layer, e.g., a low-leakage finFET device, can be produced from a bulk silicon wafer, rather than from a silicon-on-insulator wafer. In addition, embodiments of the present invention allow devices formed with semiconductor fabrication processes that are not compatible with silicon-on-insulator wafers to advantageously use an underlying electrical isolation layer. In addition, embodiments of the present invention allow devices formed with bulk silicon substrate to advantageously have lower leakage, higher current density and higher device density.

While the foregoing is directed to embodiments of the present invention, other and further embodiments of the invention may be devised without departing from the basic scope thereof, and the scope thereof is determined by the claims that follow.

1. A method for forming a device from a semiconductor substrate, the method comprising:
forming a structure from the semiconductor substrate that has a first sidewall and a second sidewall and is comprised of the material of the semiconductor substrate;
forming an oxidation barrier on the first sidewall of the structure; and
performing an isotropic oxidation process to create an insulating barrier that electrically isolates the structure from a remaining portion of the semiconductor substrate.

2. The method of claim 1, wherein forming the oxidation barrier on the first sidewall comprises conformally depositing an oxidation barrier on the semiconductor substrate including the structure, and anisotropically removing the oxidation barrier from all surfaces of the semiconductor substrate except surfaces of the structure.

3. The method of claim 1, further comprising, prior to performing the isotropic oxidation process, removing additional material from the substrate to increase a height of the structure.

4. The method of claim 3, wherein removing additional material from the substrate comprises depositing a field oxide layer on a surface of the semiconductor substrate adjacent to the structure, and removing a portion of the deposited field oxide layer.

5. The method of claim 4, wherein removing the surface portion of the field oxide layer comprises damaging and removing the portion of the deposited field oxide layer.

6. The method of claim 5, wherein damaging the portion of the deposited field oxide layer comprises performing an ion implantation process on the deposited field oxide layer.

7. The method of claim 3, wherein performing the isotropic oxidation process comprises forming an oxide from a portion of the structure that is exposed upon removing the portion of the deposited field oxide layer.

8. The method of claim 7, wherein forming the oxide comprises forming the oxide in a direction substantially perpendicular to the exposed portion of the structure to form a substantially planar interface between a top portion of the structure and the oxide.

9. The method of claim 1, further comprising forming the oxidation barrier on the second sidewall of the structure, and wherein performing the isotropic oxidation process comprises forming a portion of the electrically insulating barrier from a portion of the semiconductor substrate adjacent to the second sidewall.

10. The method of claim 1, wherein the remaining portion of the semiconductor substrate comprises an adjacent structure formed from the semiconductor substrate.

11. The method of claim 1, wherein the structure comprises a channel region that electrically couples a source region of a non-planar transistor structure and a drain region of the non-planar transistor structure.

12. The method of claim 11, wherein the channel region comprises a fin structure of a finFET device, the first sidewall comprises a first vertical sidewall of the fin structure, and the second sidewall comprises a second vertical sidewall of the fin structure.

13. The method of claim 11, wherein the channel region comprises a fin structure and the insulating barrier is configured to eliminate a leakage path between the source region of the non-planar transistor structure and the drain region of the non-planar transistor structure.

14. A semiconductor device structure, comprising:
a semiconductor structure having a first sidewall and a second sidewall, wherein the semiconductor structure is comprised of the material of the semiconductor substrate; and
an insulating barrier that electrically isolates the semiconductor structure from a remaining portion of the semiconductor substrate, wherein the electrically insulating barrier is formed from the material of the semiconductor substrate by an isotropic oxidation process.

15. The semiconductor device of claim 14, wherein the semiconductor structure includes a substantially planar interface with the electrically insulating barrier.

16. The semiconductor device of claim 15, wherein the substantially planar interface is created by forming the electrically insulating barrier from a portion of the semiconductor structure that is exposed upon removing a portion of a deposited field oxide layer.

17. The semiconductor device of claim 16, wherein the substantially planar interface is created by forming a first oxide region from a portion of the first sidewall that is exposed upon removing a portion of a deposited field oxide layer and forming a second oxide region from a portion of the second sidewall that is exposed upon removing the portion of the deposited field oxide layer.

18. The semiconductor device of claim 17, wherein the exposed portion of the semiconductor structure is exposed by damaging and removing the portion of the deposited field oxide layer.

19. The semiconductor device of claim 14, wherein the remaining portion of the semiconductor substrate from which the insulating barrier is formed is adjacent to the semiconductor structure.

20. The semiconductor device of claim 14, wherein the semiconductor structure comprises a channel region electrically coupling a source region of a non-planar transistor structure and a drain region of the non-planar transistor structure.

21. The semiconductor device of claim 20, wherein the channel region comprises a fin structure of a finFET device, the first sidewall comprises a first vertical sidewall of the fin structure, and the second sidewall comprises a second vertical sidewall of the fin structure.

22. The semiconductor device of claim 20, wherein the channel region comprises a fin structure and the insulating barrier is configured to eliminate a leakage path between the source region of the non-planar transistor structure and the drain region of the non-planar transistor structure.
